(19) United States
(12) Patent Application Publication
(10) Pub. No.: US 2025/0231543 A1
(43) Pub. Date: Jul. 17, 2025

(54) MANUFACTURING APPARATUS AND OPERATING METHOD OF MANUFACTURING APPARATUS

(71) Applicant: HITACHI HIGH-TECH CORPORATION, Minato-ku, Tokyo (JP)

(72) Inventors: Mitsuhiro HIRANAKA, Tokyo (JP); Takahiro ICHIKAWA, Tokyo (JP); Makoto KASHIBE, Tokyo (JP)

(21) Appl. No.: 18/691,343

(22) PCT Filed: Mar. 29, 2023
(86) PCT No.: PCT/JP2023/012813

§ 371 Date: Mar. 12, 2024

(51) Int. Cl. G05B 19/042

(52) U.S. Cl. CPC G05B 19/0423; G05B 2219/2231

(57) ABSTRACT

An object of the invention is to provide a technique capable of improving efficiency of work performed on an apparatus. According to one typical aspect of the invention, there is provided a manufacturing apparatus including: a plurality of component devices; and a control unit configured to transmit data signals to the plurality of component devices. The plurality of component devices are categorized as groups by a function, and have one or more groups including a first slave device group including at least one component device among the plurality of component devices, and a second slave device group including at least one component device among component devices excluding the component device provided in the first slave device group from the plurality of component devices, and the control unit transmits the data signals to the first slave device group and the second slave device group.

### TECHNICAL FIELD

The present invention relates to a manufacturing apparatus and an operating method of the manufacturing apparatus.

### BACKGROUND ART

A control system supporting social infrastructure includes a sensor, a controller, and an actuator. In the control system, a state of a physical object is acquired by the sensor and input to the controller, a control command value for the controller to instruct the actuator is calculated, and the actuator works on the physical object based on the control command value. For example, desired control is executed by periodically repeating such a series of processing.

Such a control system is also used in a semiconductor manufacturing apparatus that manufactures a semiconductor device by processing a semiconductor wafer or the like, or a semiconductor inspection apparatus. For example, it has been considered in related art to use such a control system in a plasma processing apparatus that forms a circuit structure of a semiconductor device by etching, using plasma, a film layer to be processed among a plurality of film layers formed in advance on a semiconductor wafer disposed in a processing chamber inside a vacuum container.

Since a large number of semiconductor manufacturing apparatuses are installed in a building, a plurality of sensors, controllers, and actuators are connected to form a network in a control system that controls an operation of the plurality of semiconductor manufacturing apparatuses. In such a network, a technique has been developed in order to satisfy a temporal constraint (for example, an allowable maximum delay time), a cost, reliability, and a field-specific requirement, which are requirements for the control system. Therefore, in particular, it is also required for the network of the semiconductor manufacturing apparatus to respond to an increase in a scale and sophistication of the control system, an increase in a communication speed in the network technique, shortening of a control communication cycle, an increase in communication capacity, and the like.

As a method for meeting such needs, there is a technique of transmitting communication packets in parallel using a plurality of communication ports. That is, a communication delay is shortened by distributing target communication device groups and performing communication in parallel, resulting in the increase in the communication speed, the shortening of the control communication cycle, and the increase in the communication capacity.

As a method that controls such communication, there is known one disclosed in JP2021-015855A (PTL 1). A performance calculation method disclosed in PTL 1 includes: acquiring shipping inspection data on a plurality of flow controllers; calculating a first performance value representing performance of each flow controller as a deviation value based on the acquired shipping inspection data and a first coefficient for each item indicating the performance of the flow controller; and calculating a second performance value representing performance of a processing apparatus as a deviation value based on the calculated first performance value and a second coefficient for each item indicating the performance of the processing apparatus using the flow controller. The technique disclosed in PTL 1 is an industrial Ethernet (registered trademark) technique in which communication is performed with a plurality of devices connected to a plasma processing apparatus, and EtherCAT (registered trademark) is used in which communication is performed in one frame for transmission and reception process data of all nodes in a network segment.

### CITATION LIST

### Patent Literature

PTL 1: JP2021-015855 A

### SUMMARY OF INVENTION

### Technical Problem

However, the EtherCAT used in PTL 1 is basically required to coincide electronic information (ENI file) describing a connection order of components (devices) connected thereto with the connection and order of the components. Therefore, it is known that a hot connect function is utilized to connect a group (slave) of a plurality of components to a master, whereby communication can be established even if the electronic information does not coincide with the components, allowing connection and removal of some components.

However, in the related art, when one component connected as a device belonging to any slave is removed for maintenance or changing to a component having new specifications, if the master is regarded as a component on the most upstream side, this component cannot communicate with other slave devices on a downstream side.

For example, it is difficult to perform work such as maintenance or replacement on a specific component among the plurality of components connected to the plasma processing apparatus in parallel with an operation of the plasma processing apparatus and work such as maintenance or replacement on other components. Therefore, efficiency of the work performed on the plasma processing apparatus is impaired.

The fact that it is difficult to perform work such as maintenance and replacement in parallel is considered to be able to be solved by connecting a plurality of hubs each including one port for connecting a slave component to the master, and connecting one slave component to each port. However, in the master, the number of necessary hubs increases depending on the number of components connected as slaves to the plasma processing apparatus, resulting in problems such as an increase in an installation area and complicated routing in wiring. Such problems have not been sufficiently taken into consideration in the related art.

An object of the invention is to provide a technique capable of improving efficiency of work performed on an apparatus.

### Solution to Problem

In order to solve the above problems, according to one aspect of the invention, there is provided a manufacturing apparatus including: a plurality of component devices; and a control unit configured to transmit data signals to the plurality of component devices. The plurality of component devices are categorized as groups by a function, and have one or more groups including a first slave device group including at least one component device among the plurality of component devices, and a second slave device group including at least one component device among component devices excluding the component device provided in the first slave device group from the plurality of component devices, and the control unit transmits the data signals to the first slave device group and the second slave device group.

### Advantageous Effects of Invention

According to the invention, a technique capable of improving efficiency of work performed on an apparatus can be provided.

Problems, configurations, and effects other than those described above will become apparent in the description in embodiments as follows.

### BRIEF DESCRIPTION OF DRAWINGS

FIG. 1 is a diagram schematically showing an outline of a configuration of a plasma processing apparatus according to Embodiment 1.

FIG. 2 is a block diagram schematically showing an example of a control unit and component devices (components) connected thereto according to Embodiment 1.

FIG. 3 is a block diagram schematically showing an example of the control unit and slave device groups connected thereto of the plasma processing apparatus according to Embodiment 1.

FIG. 4 is a flowchart schematically showing a flow of maintenance work on a plurality of components in the control unit and the slave device groups shown in FIG. 3.

FIG. 5 is a block diagram schematically showing an example of a control unit and components connected thereto of a plasma processing apparatus as a comparative example with respect to FIG. 3.

FIG. 6 is a block diagram schematically showing an example of a control unit and slave device groups connected thereto of a plasma processing apparatus according to Embodiment 2.

### DESCRIPTION OF EMBODIMENTS

Hereinafter, embodiments of the invention will be described with reference to the drawings. The invention is not limited to the embodiments. In the description of the drawings, the same portions are denoted by the same reference numerals.

When there are a plurality of components having the same or similar functions, the same reference numerals may be assigned with different subscripts. However, when it is not necessary to distinguish the plurality of components, the subscripts may be omitted from the description.

The disclosure will be described on the assumption that, in a communication method using EtherCAT, after confirming a network configuration, a master device assigns a fixed address to each component provided in a network and uses the fixed address for communication with the component. Accordingly, the master device can handle a designated component as a slave device and transmit a command signal.

Further, it is assumed that the master device having an EtherCAT function has a hot connect function. Therefore, even when a component in a network operation state such as a state in which the component is energized and in communication is detached, the master device can designate other components constituting the network.

A beaded manner (daisy chain) refers to a situation in which a main connection system of devices is connected only in series and is not connected to other devices by branching. Here, the main connection system means connection for transmitting information such as a control signal from a control unit.

### Embodiment 1

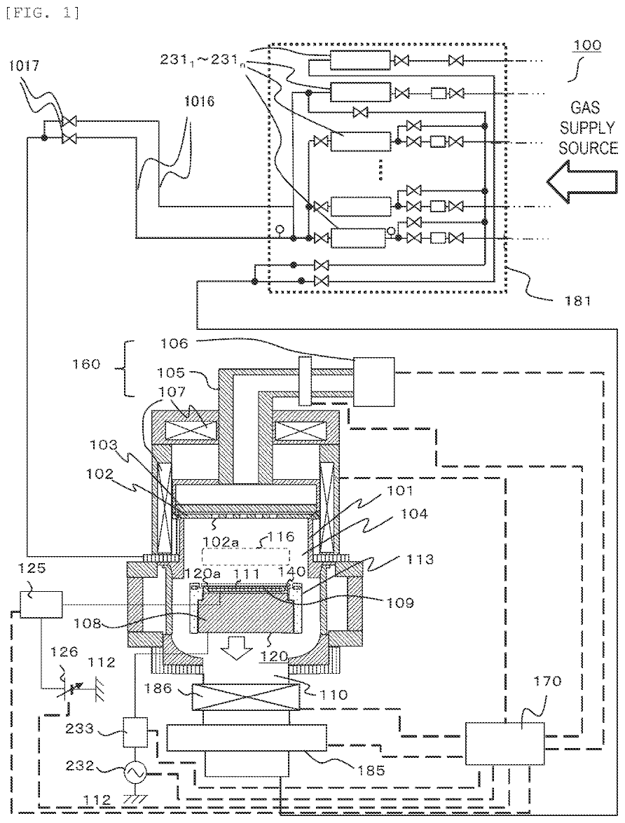

Hereinafter, Embodiment 1 will be described with reference to FIGS. 1 to 5.

### (Configuration of Plasma Processing Apparatus)

FIG. 1 is a diagram schematically showing an outline of a configuration of a plasma processing apparatus 100 according to Embodiment 1. The plasma processing apparatus (manufacturing apparatus) 100 includes a plurality of component devices and a control unit that transmits data signals to the plurality of component devices. The plasma processing apparatus 100 uses a microwave electric field as an electric field for forming plasma, generates electron cyclotron resonance (ECR) between the microwave electric field and a magnetic field to form the plasma, and etches a substrate-shaped sample such as a semiconductor wafer using the plasma.

The plasma processing apparatus 100 includes a vacuum container 101 having therein a processing chamber 104 in which the plasma is formed. In the processing chamber 104 having a cylindrical upper portion, a dielectric window 103 (for example, made of quartz) having a circular plate shape is placed as a cover member to constitute a part of the vacuum container 101. A seal member such as an O-ring is disposed between the cylindrical vacuum container 101 and the dielectric window 103 to ensure airtightness inside the vacuum container 101 or the processing chamber 104.

A vacuum exhaust port 110 connected to the processing chamber 104 is disposed in a lower portion of the vacuum container 101, and communicates with a vacuum pump 185 disposed and connected below the vacuum container 101. Further, a shower plate 102 constituting a circular ceiling surface of the processing chamber 104 is provided below the dielectric window 103. The shower plate 102 has a circular plate shape having a plurality of gas introduction holes 102a formed through a central portion thereof, and an etching processing gas is introduced into the processing chamber 104 through the gas introduction holes 102a. The shower plate 102 is made of a dielectric material such as quartz.

An electric field and magnetic field formation unit 160 that forms an electric field and a magnetic field for generating plasma 116 is disposed above the vacuum container 101. The electric field and magnetic field formation unit 160 includes a waveguide 105 and an electric field generation power source 106, and a radio frequency electric field oscillated from the electric field generation power source 106 is transmitted through the waveguide 105 and introduced into the processing chamber 104. The electric field generation power source 106 according to the embodiment is a microwave power source that uses, for example, a microwave of 2.45 GHZ as a frequency of an electric field to be formed. As will be described later, the electric field generation power source 106 includes a microwave power source 235 and a microwave power source matching device 236.

Magnetic field generation coils 107 are disposed around a lower end of the waveguide 105 and around the vacuum container 101. The magnetic field generation coil 107 includes an electromagnet and a yoke to which a direct current is supplied to form a magnetic field.

In a state in which a processing gas is introduced into the processing chamber 104 through the gas introduction holes 102a in the shower plate 102, the microwave electric field oscillated by the electric field generation power source 106 propagates through the waveguide 105, passes through the dielectric window 103 and the shower plate 102, and is supplied downward to the processing chamber 104 from above. Further, the magnetic field generated by the direct current supplied to the magnetic field generation coil 107 is supplied into the processing chamber 104, and interacts with the microwave electric field to generate electron cyclotron resonance (ECR). By the ECR, atoms or molecules of the processing gas are excited, dissociated, or ionized, and the high-density plasma 116 is generated in the processing chamber 104.

A wafer placement electrode 120 is disposed below a space where the plasma 116 is formed. The wafer placement electrode 120 includes, in a central portion of an upper portion thereof, a cylindrical protruding portion whose upper surface is higher than an outer peripheral side, and the upper surface of the protruding portion includes a placement surface 120a on which a semiconductor wafer (hereinafter, also simply referred to as a wafer) 109 as a sample (to be processed) is placed. The placement surface 120a is disposed to face the shower plate 102 or the dielectric window 103.

The wafer placement electrode 120 includes an electrode base material 108, a dielectric film 140 provided on the electrode base material 108, and a susceptor ring 113.

The electrode base material 108 includes a protruding portion (protrusion) in a central portion of an upper portion thereof and a recessed portion (recess) surrounding the protruding portion. In a plan view, a protruding portion having a circular shape is located at the central portion of the electrode base material 108, and a ring-shaped recessed portion is located around the protruding portion. The protruding portion has a circular upper surface in the plan view, and the upper surface of the protruding portion is covered with the dielectric film 140. An upper surface of the dielectric film 140 constitutes a placement surface on which the semiconductor wafer 109 is placed, the placement surface has a circular shape in the plan view, a radius of the placement surface is equal to a radius of the upper surface of the dielectric film 140, and centers of both circular shapes overlap with each other.

A plurality of conductor films 111, which are films made of conductors, are disposed inside the dielectric film 140. The conductor film 111 is connected to a DC power source 126 via a radio frequency filter 125. When DC power is supplied to the conductor film 111, the semiconductor wafer 109 is adsorbed on the placement surface via the dielectric film 140 on the conductor film 111. The conductor film 111 is an electrode for electrostatic adsorption. For convenience, the protruding portion (protrusion) of the electrode base material 108 and the dielectric film 140 including the conductor films 111 are referred to as a sample stage ST.

The electrode base material 108 is connected to a radio frequency power source (RF power source) 232 via a radio frequency power source matching device (RF matching device) 233. The radio frequency power source 232 and the radio frequency power source matching device 233 are disposed at positions closer than a distance between the radio frequency filter 125 and the conductor film 111. Further, the radio frequency power source 232 is connected to a ground 112. One set of the radio frequency power source matching device 233 and the radio frequency power source 232 may be provided, or a plurality of sets of matching devices and radio frequency power sources may be provided. That is, a plurality of radio frequency power sources (RF power sources) 232₁ to 232ₘ are connected to the electrode base material 108 via a plurality of radio frequency power source matching devices 233₁ to 233ₘ, respectively. When the plurality of radio frequency power sources 232₁ to 232ₘ are used, a radio frequency (RF) mixer 234 may be provided as described later.

In processing the semiconductor wafer 109, radio frequency power of a predetermined frequency is supplied from at least one radio frequency power source 232 or the plurality of radio frequency power sources 232₁ to 232ₘ to the electrode base material 108 (that is, the sample stage ST). A bias potential having a distribution corresponding to a difference between a potential of the plasma 116 and a potential of the electrode base material 108 is formed above the semiconductor wafer 109 adsorbed and held on the placement surface via the dielectric film 140.

In order to cool the wafer placement electrode 120, inside the electrode base material 108, multiple refrigerant flow paths arranged spirally or concentrically around a central axis of the electrode base material 108 in an upper-lower direction are provided. An inlet and an outlet of a refrigerant flow path to the wafer placement electrode 120 are connected to a temperature controller, which includes a refrigeration cycle (not shown) and adjusts a temperature of a refrigerant to a temperature within a predetermined range by heat transfer, and a pipeline, and the refrigerant having the temperature changed due to heat exchange by flowing through the refrigerant flow path flows out from the outlet, passes through a flow path inside the temperature controller via the pipeline, is set to a predetermined temperature range, and is then supplied to the refrigerant flow path in the electrode base material 108 to be circuited.

The ring-shaped susceptor ring 113 surrounding the protruding portion is placed in the recessed portion of the electrode base material 108. The susceptor ring 113 is formed of at least one member made of a dielectric material, for example, ceramics such as quartz or alumina. Since side surfaces of the electrode base material 108 and a bottom surface of the recessed portion thereof are at least covered with the susceptor ring 113, the electrode base material 108 can be prevented from being further damaged by plasma.

As shown in FIG. 1, the electric field generation power source 106, the magnetic field generation coil 107, the radio frequency power source 232, the radio frequency filter 125, the DC power source 126, the radio frequency power source matching device 233, and the like are communicably connected to a control unit 170 in a wired or wireless manner, as indicated by broken lines. A detailed configuration of the control unit 170 will be described later.

In the embodiment, for example, the processing gas is supplied through piping that extends from a gas supply source for each gas type disposed below a floor surface of a building in which the plasma processing apparatus 100 is installed and that is connected to the vacuum container 101. A plurality of pipelines divided for a plurality of types of gases therein and an integrated gas box 181 having a box shape including mass flow controllers (MFC) 231₁ to 231ₙ that are disposed on the pipelines and each adjusts a flow rate or a speed of each type of gas are disposed on the piping. Inside the integrated gas box 181, pipelines for supplying processing gases are merged into a plurality of gas supply pipes 1016 and extend to the outside of the integrated gas box 181.

A flow of the gas introduced into a gap between the dielectric window 103 and the shower plate 102, diffused, and supplied to the processing chamber 104 through the gas introduction holes 102a is adjusted by opening or closing an opening and closing valve 1017 disposed on the gas supply pipe 1016. In the embodiment, a mixed gas of a reactive gas that is reactive with a film to be processed on an upper surface of the semiconductor wafer 109 or that is reactive inside the plasma 116 and an inert gas that dilutes the reactive gas is used as the processing gas.

The vacuum pump 185 such as a turbomolecular pump for exhausting and depressurizing the gas inside the processing chamber 104 is disposed and connected below the processing chamber 104. The vacuum pump 185 is connected to the vacuum container 101 constituting a bottom surface of the processing chamber 104 via an exhaust amount adjustment valve 186 that adjusts a flow rate or a speed of exhaust by increasing or decreasing an area of a flow path.

### (Plasma Processing Method)

Next, a plasma processing method using the above plasma processing apparatus 100 will be described.

First, the above plasma processing apparatus 100 is prepared.

Next is a step of loading the semiconductor wafer 109. A vacuum transfer chamber depressurized to the same pressure as the processing chamber 104 is connected to a sidewall of the vacuum container 101. The semiconductor wafer 109 is placed on an arm tip end of a wafer transfer robot disposed in the vacuum transfer chamber and is loaded into the processing chamber 104. Next, the semiconductor wafer 109 is placed on the placement surface, and is electrostatically adsorbed and held on the sample stage ST.

Next is an etching gas introduction step. After the transfer robot exits the vacuum transfer chamber, the inside of the processing chamber 104 is sealed. In this state, an etching processing gas is supplied into the processing chamber 104. The introduced gas is introduced into the processing chamber 104 through the gas introduction holes 102a in the shower plate 102.

The gas and particles inside the processing chamber 104 are exhausted through the vacuum exhaust port 110 by an operation of the vacuum pump 185 connected to the vacuum exhaust port 110. The inside of the processing chamber 104 is adjusted to a predetermined pressure suitable for processing the semiconductor wafer 109 according to a balance between a supply amount of the gas from the gas introduction holes 102a in the shower plate 102 and an exhaust amount from the vacuum exhaust port 110.

Next is a plasma etching (plasma processing) step. Although details are omitted, after a temperature of the semiconductor wafer 109 is adjusted as necessary, a microwave electric field and a magnetic field are supplied into the processing chamber 104, and the plasma 116 is generated using the gas. When the plasma 116 is formed, radio frequency (RF) power is supplied from a radio frequency power source 124 to the electrode base material 108, a bias potential is formed above the upper surface (main surface) of the semiconductor wafer 109, and charged particles such as ions in the plasma 116 are attracted to the upper surface of the semiconductor wafer 109 according to a potential difference with a potential of the plasma 116.

Further, the charged particles collide with a surface of a film layer to be processed, which is disposed in advance on the upper surface of the semiconductor wafer 109, and etching is performed. During etching, the processing gas introduced into the processing chamber 104 or particles of a reaction product generated during the processing are exhausted from the vacuum exhaust port 110.

Next is a step of unloading the semiconductor wafer 109. The semiconductor wafer 109 after etching is supported by the arm tip end of the transfer robot and carried out of the processing chamber 104.

### (Configuration of Control Unit)

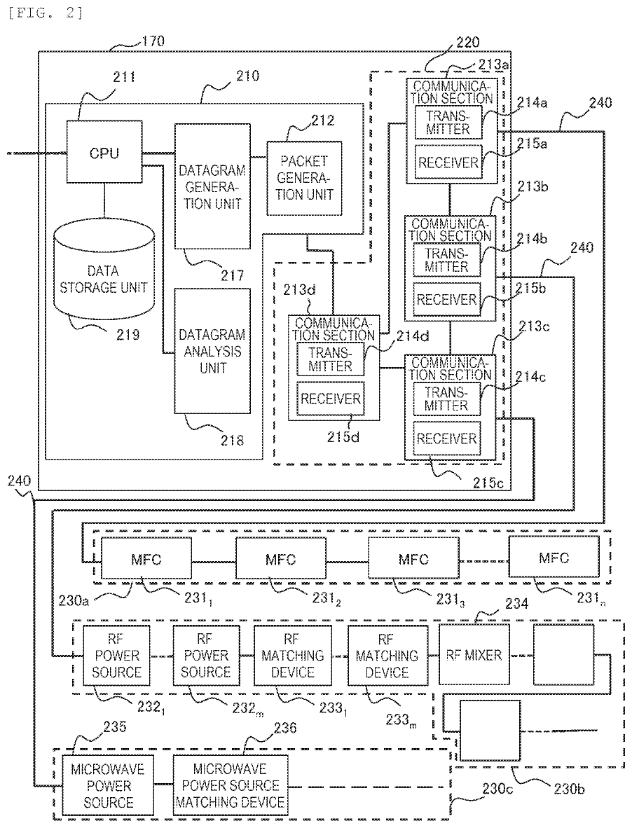

Next, details of a configuration and functions of the control unit 170 shown in FIG. 1 will be described. FIG. 2 is a block diagram schematically showing an example of the control unit 170 and component devices (components) connected thereto according to Embodiment 1. A plurality of component devices are categorized as groups by functions thereof, and have one or more groups including a first slave device group including at least one component device among the plurality of component devices and a second slave device group including at least one component device among component devices excluding the component device provided in the first slave device group from the plurality of component devices, and the control unit 170 transmits data signals to the first slave device group and the second slave device group. The control unit 170 includes a master device that generates a data signal, and a hub 220 that is connected to the master device and includes at least a first communication section and a second communication section. The first slave device group is connected to the first communication section of the hub 220, and the second slave device group is connected to the second communication section of the hub 220. In the embodiment, the control unit 170 includes a master device 210 and the hub 220. The hub 220 is directly communicably connected to the master device 210, and includes a plurality of (three in the embodiment) communication sections (ports) 213a to 213c connected to the slave device groups 230a to 230c, respectively. By providing the hub 220, the master device 210 is communicably connected to the slave device groups 230a to 230c each having at least one component.

In the control unit 170, the master device 210 generates data signals to be transmitted to a plurality of components. The master device 210 transmits data to and receives data from, via the ports of the hub 220, components of each of the slave device groups 230a to 230c connected to the ports. Further, the components belonging to the slave device groups 230a to 230c connected to the ports of the hub 220 are controlled based on command signals or data signals from the master device 210. In the embodiment, the hub 220 directly connected to the master device 210 includes at least one port, and a plurality of components are connected to each port of the master in a beaded manner (daisy chain). The slave device groups 230a to 230c are connected in a beaded manner via the hub 220. The control unit 170 and the slave device groups 230a to 230c follow a communication method using EtherCAT.

The master device 210 includes, for example, a CPU 211 and a data storage unit 219 including a memory and a RAM. The master device 210 may include a datagram generation unit 217 that generates control data and command signals for the components belonging to the slave device groups 230a to 230c.

The components provided in the plurality of slave device groups 230a to 230c are communicably connected to the master device 210 via the ports of the hub 220 in a daisy chain form. As the components according to the embodiment, the slave device group 230a includes a mass flow controller (MFC) 231₁, a mass flow controller (MFC) 231₂, a mass flow controller (MFC) 231₃, . . . , and a mass flow controller (MFC) 231ₙ (n is a positive integer). Further, the slave device group 230b includes the plurality of radio frequency power sources 232₁ to 232ₘ (m is a positive integer), the radio frequency power source matching devices 233₁ to 232ₘ for the radio frequency power sources, and the radio frequency mixer 234, and the slave device group 230c includes the microwave power source 235 and the microwave power source matching device 236 as a matching device for the microwave power source.

The components provided in the slave device groups 230a to 230c are not limited thereto. Other components can be provided in the slave device groups 230a to 230c.

In the embodiment, the master device 210 communicates command signals or data with the plurality of slave device groups 230a to 230c and the components belonging thereto via a transmission path 240 at a predetermined cycle. In the embodiment, three slave device groups 230a to 230c are shown as being communicably connected to the master device 210, but the number of slave device groups 230 is not limited to three, and may be one, two, or three or more. Although the transmission path 240 is shown by one line, the transmission path 240 includes two transmission paths, that is, a transmission path for transmission signals and a transmission path for reception signals. A LAN cable or the like can be used as the transmission path 240.

As shown in FIG. 2, the master device 210 includes at least one packet generation unit 212 and at least one hub 220.

The hub 220 includes a communication section 213d communicably connected to the packet generation unit 212 and a datagram analysis unit 218 to be described later. In the hub 220, the communication section 213d is communicably connected to the communication sections 213a and 213c, and the communication section 213b is communicably connected to the communication sections 213a and 213c. The communication section 213d is an interface on the master device 210 side. A transmitter 214d of the communication section 213d transmits a signal to the communication section 213a and transmits a signal to the datagram analysis unit 218 of the master device 210. A receiver 215d of the communication section 213d receives a signal from the communication section 213c and receives a signal from the packet generation unit 212 of the master device 210.

The communication sections 213a to 213c are interfaces on a slave device groups 230a to 230c side. Each of the communication sections 213a to 213c includes, as a pair, one of transmitters 214a to 214c that transmit packets (data signals), which are command signals or signals constituting data created by the packet generation unit 212, to the connected slave device groups 230a to 230c, and one of receivers 215a to 215c that receive signals including data from the slave device groups 230a to 230c.

Packets received by the receivers 215a to 215c include data indicating states of the devices from the components belonging to the slave device groups 230a to 230c and signals of responses requested in the command signals. In the embodiment, signals including the packets transmitted from the transmitters 214a to 214c are sequentially received via the ports by the components belonging to the slave device groups 230a to 230c and connected in a daisy chain form, and then the signals are returned from components connected at the most downstream position to the most upstream master device 210. The packet returned to the master device 210 is transmitted to the datagram analysis unit 218, a connection state of the daisy chain of the components belonging to each of the slave device groups 230a to 230c is analyzed, and the CPU 211 creates a command signal for causing a necessary operation of the components.

The master device 210 adjusts the operation of the components belonging to the slave device groups 230a to 230c. For example, the master device 210 adjusts a flow rate of a gas flowing through a gas flow path where the MFC 231₁ is disposed. In the embodiment, the CPU 211 receives a packet returned through the slave device groups 230a to 230c, or transmits a signal to the datagram generation unit 217 according to a predetermined process, procedure, or recipe stored in advance in the data storage unit 219, in response to a command signal from a host computer (not shown) that transmits a command signal to a plurality of semiconductor manufacturing apparatuses including the plasma processing apparatus 100 in a building where the plasma processing apparatus 100 is installed and adjusts an operation thereof. The CPU 211 causes the datagram generation unit 217 to generate a datagram in which a command signal and data for adjusting an operation of at least one component of each of the slave device groups 230a to 230c are arranged in a predetermined order. The datagram generated by the datagram generation unit 217 is transmitted to the packet generation unit 212.

The packet generation unit 212 generates a command signal or data (control data) for adjusting an operation of at least one component connected to the corresponding one of the slave device groups 230a to 230c to be adjusted, specifically, data for instructing an operation of processing the semiconductor wafer 109 as a step of manufacturing a semiconductor device in the plasma processing apparatus 100. The packet generation unit 212 is disposed in the master device 210 and generates data according to the components of the slave device groups 230a to 230c.

The packet generation unit 212 generates data for adjusting operations of the mass flow controller 231₁, the mass flow controller 231₂, and the mass flow controller 231₃ (for example, a flow rate of each mass flow controller or an opening or closing operation of the flow path) connected to the corresponding communication section 213a, for example, for the slave device group 230a. Similarly, the packet generation unit 212 generates data for adjusting operations of the plurality of radio frequency power sources 232₁ to 232ₘ, the radio frequency power source matching devices 233₁ to 233ₘ for the radio frequency power sources, and the radio frequency mixer 234 connected to the corresponding 213b, for example, for the slave device group 230b. Similarly, the packet generation unit 212 generates data for adjusting operations of the microwave power source 235 and the microwave power source matching device 236 connected to the corresponding 213c, for example, for the slave device group 230c.

In this way, the packet generation unit 212 generates data for the components connected to each of the slave device groups 230a to 230c in association with the components, and stores the data inside one packet. The packet may include a command signal for at least one specific component.

The communication sections 213a to 213c of the hub 220 according to the embodiment transmit packets including command signals and data (instruction data) received from the packet generation unit 212 to the plurality of slave device groups 230a to 230c and the components belonging thereto via the transmission path 240 at a predetermined cycle. Similarly, the communication sections 213a to 213c receive signals including data as responses to signals returned from the components of the slave device groups 230a to 230c. Here, the response data may include, for example, data indicating whether the processing instructed by the instruction data is normally completed.

The datagram generation unit 217 receives an instruction signal from the CPU 211 and writes instruction data generated as a packet in the packet generation unit 212 into a datagram or a data frame at predetermined intervals. The generated datagram or data frame is transmitted to the packet generation unit 212.

The datagram analysis unit 218 executes processing of acquiring data indicating a state of an operation of each component from response data obtained from each of the slave device groups 230a to 230c at a predetermined cycle. The data indicating the state of the operation may include, for example, data indicating a state in which the slave device groups 230a to 230c or the components belonging thereto are normally operating, or data indicating a state in which an abnormality occurs in the slave device groups 230a to 230c.

Further, the data obtained by the datagram analysis unit 218 is transmitted to the CPU 211, and a command signal and data are calculated based on the data. Further, a cycle in which a packet is transmitted to each of the slave device groups 230a to 230c and processing is executed by the slave device groups 230a to 230c and a cycle in which processing of acquiring data indicating a state of an operation from response data is executed are calculated.

In the embodiment, in a network configured with the master device 210, the hub 220, and the slave device groups 230a to 230c shown in FIG. 2, EtherCAT that is one of industrial Ethernets is used as the communication method. In the EtherCAT, the master device 210 connected thereto transmits datagrams to the plurality of slave device groups 230a to 230c, and the components provided in the plurality of slave device groups 230a to 230c read data from and write data to the datagrams received from the master device 210 in an on-the-fly manner. At this time, communication between the master device 210 and the plurality of slave device groups 230a to 230c is performed at a specific cycle using data called a process data object (PDO).

Communication is performed according to a request from the master device 210 using data called a service data object (SDO). In the embodiment in which the EtherCAT is used as the communication method of the network, at least one node among nodes connected to the transmission path 240 functions as the master device 210, and the other nodes function as the slave device groups 230a to 230c (or the components belonging thereto). The master device 210 manages (adjusts) a timing of datagram communication in the network.

The communication sections 213a to 213c of the master device 210 according to the embodiment transmit packets generated by the packet generation unit 212 based on datagrams including instruction data to the connected slave device groups 230a to 230c. The components of each of the slave device groups 230a to 230c that received the packet write response data for the instruction data in the datagram, according to instruction data assigned thereto from the instruction data written in the datagram transmitted as the packet. Then, the slave device groups 230a to 230c transmit the packets based on the datagrams in which the response data for the instruction data assigned thereto is written, to the communication sections 213a to 213c via the ports of the hub 220 to which the slave device groups 230a to 230c to which the packets belong are connected.

The packets received by the receivers 215a to 215c are transmitted to the datagram analysis unit 218 of the master device 210, response data included in the packets is detected, and the response data is transmitted to the CPU 211. The data transmitted and received between the master device 210 and the slave device groups 230a to 230c (and the components belonging thereto) may include not only the instruction data and the response data but also state data on the components of the slave device groups 230a to 230c.

### (Packet Flow)

Here, a flow of packets (data signals) between the master device 210 and the slave device groups 230a to 230c will be specifically described. First, the master device 210 transmits a packet generated by the packet generation unit 212 to the communication section 213d of the hub 220. The communication section 213d receives the packet transmitted from the master device 210 by the receiver 215d, and transmits the packet to the communication section 213a by the transmitter 214d.

The communication section 213a receives the packet from the communication section 213d by the receiver 215a. The communication section 213a transmits the packet to the slave device group 230a by the transmitter 214a. In the slave device group 230a, the packet is sequentially transmitted to the MFC 231₁, the mass flow controller 231₂, the mass flow controller 231₃, . . . , and the mass flow controller 231ₙ. The packet that reaches the mass flow controller 231ₙ returns from the mass flow controller 231ₙ₋₁, . . . , to the mass flow controller 231₃, the mass flow controller 231₂, and the mass flow controller 231₁. The communication section 213a receives the packet circuited through the slave device group 230a by the receiver 215a. The communication section 213a transmits the packet to the communication section 213b by the transmitter 214a.

Subsequently, the communication section 213b receives the packet from the communication section 213a by the receiver 215b. The communication section 213b transmits the packet to the slave device group 230b by the transmitter 214b. In the slave device group 230b, the packet is sequentially transmitted from the radio frequency power source 232₁ to the radio frequency power source 232ₘ, from the radio frequency power source matching device 233₁ to the radio frequency power source matching device 233ₘ, and to the radio frequency mixer 234. The packet that reaches a component connected on the most downstream side of the slave device group 230b returns to the radio frequency power source 232₁ via components of the slave device group 230b. The communication section 213b receives the packet circuited through the slave device group 230b by the receiver 215b. The communication section 213b transmits the packet to the communication section 213c by the transmitter 214b.

Subsequently, the communication section 213c receives the packet from the communication section 213b by the receiver 215c. The communication section 213c transmits the packet to the slave device group 230c by the transmitter 214c. In the slave device group 230c, the packet is sequentially transmitted through the microwave power source 235 and the microwave power source matching device 236. The packet that reaches a component connected on the most downstream side of the slave device group 230c returns to the microwave power source 235 via components of the slave device group 230c. The communication section 213c receives the packet circuited through the slave device group 230c by the receiver 215c. The communication section 213c transmits the packet to the communication section 213d by the transmitter 214c.

Finally, the communication section 213d receives the packet by the receiver 215d. The communication section 213d transmits the packet to the datagram analysis unit 218 of the master device 210 to be described later.

In this way, the packet transmitted from the master device 210 circuits between the hub 220 and the slave device groups 230a to 230c and returns to the master device 210. A way of combining the communication sections 213a to 213c and the slave device groups 230a to 230c is not limited thereto. The communication section to which the slave device group is connected can be appropriately selected.

### (Operating Method)

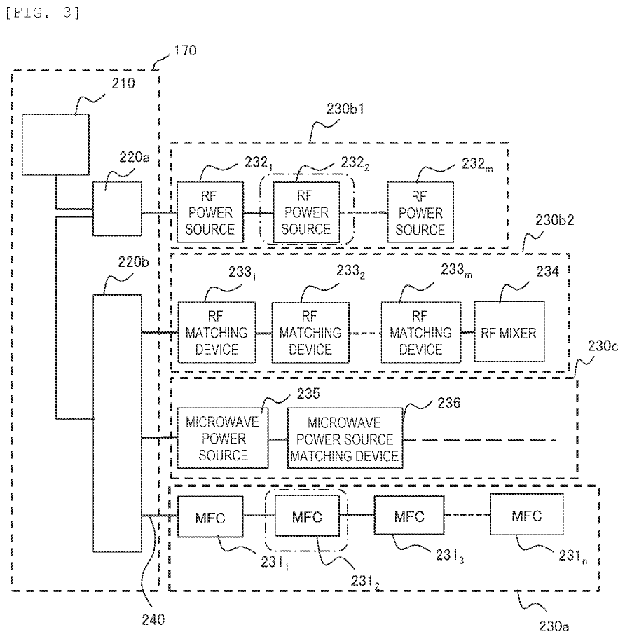

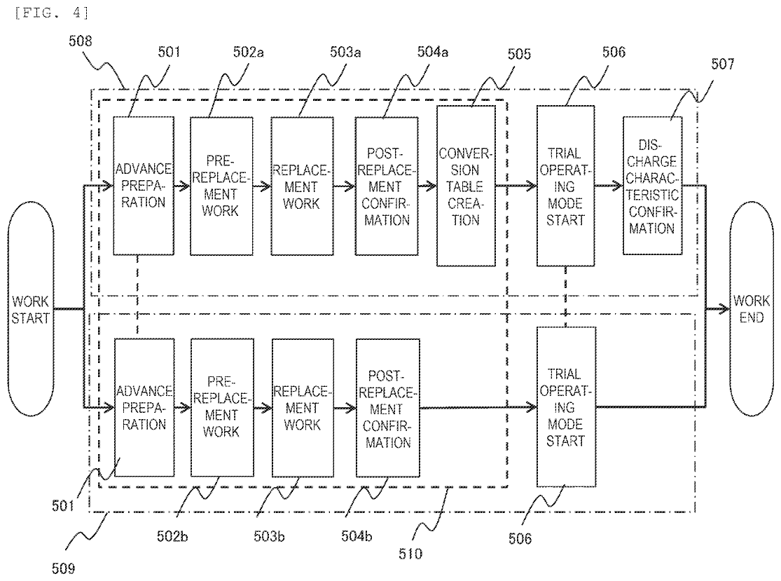

Next, an example of a configuration of the control unit 170 and slave device groups according to Embodiment 1 and a flow of maintenance work on the components belonging to the slave device groups will be described with reference to FIGS. 3 and 4. FIG. 3 is a block diagram schematically showing the example of the control unit 170 and the slave device groups connected thereto of the plasma processing apparatus according to Embodiment 1.

FIG. 3 show a hub 220a and a hub 220b instead of the hub 220 in FIG. 2. In FIG. 3, the hub 220a is directly connected to the master device 210 constituting the control unit 170, and the hub 220b is connected to the hub 220a. The hub 220a and the hub 220b include a plurality of communication sections, and are communicably connected via the communication sections. Specifically, a slave device group 230b1 is connected to the hub 220a, and slave device groups 230b2, 230c, and 230a are connected to the hub 220b. A plurality of component devices connected to the two hubs 220a and 220b are divided into four groups according to a predetermined purpose, and adjacent components in each group are communicably connected in a beaded manner.

For describe a packet flow specifically, the hub 220a receives a packet transmitted from the master device 210. The hub 220a transmits the packet to the slave device group 230b1. In the slave device group 230b1, the packet circuits from the radio frequency power source 232₁ to the radio frequency power source 232ₘ. The hub 220a receives the packet circuited through the slave device group 230b1. The hub 220a transmits the packet to the hub 220b.

The hub 220b receives the packet from the hub 220a. The hub 220b transmits the packet to the slave device group 230b2. In the slave device group 230b2, the packet circuits from the radio frequency power source matching device 233₁ to the radio frequency mixer 234. The hub 220b receives the packet circuited through the slave device group 230b2 and transmits the packet to the slave device group 230c. In the slave device group 230c, the packet circuits from the microwave power source 235 to a component connected on the most downstream side of the slave device group 230c. The hub 220b receives the packet circuited through the slave device group 230c and transmits the packet to the slave device group 230a. In the slave device group 230a, the packet circuits from the mass flow controller 231₁ to the mass flow controller 231ₙ.

The hub 220b receives the packet circuited through the slave device group 230a. The hub 220b transmits the packet to the hub 220a, and the hub 220a transmits the packet to the master device 210.

The slave device group 230b1 includes the radio frequency power sources 232₁ to 232ₘ that form a bias potential above the semiconductor wafer 109 placed on the dielectric film 140 of the wafer placement electrode 120, which are connected in a beaded manner in this order. In addition, the slave device group 230b2 includes the plurality of radio frequency power source matching devices 233₁ to 233ₘ respectively corresponding to the radio frequency power sources 232₁ to 232ₘ, and the radio frequency mixer 234, which are connected in a beaded manner in this order. In FIG. 3, components belonging to the slave device groups 230b1 and 230b2 are clearly divided, and some of the components belonging to one slave device group are not attached as components belonging to the other slave device group during an operation of the plasma processing apparatus.

Similarly, the slave device group 230c includes the microwave power source 235 for plasma formation of the plasma processing apparatus 100, and the microwave power source matching device 236, which are connected in a beaded manner. The slave device group 230a includes the mass flow controller 231₁, the mass flow controller 231₂, and the mass flow controller 231₃ to the mass flow controller 231ₙ, which are connected in a beaded manner.

The microwave power source 235 constitutes the electric field generation power source 106 disposed in an upper portion of the plasma processing apparatus 100, and is a power source that forms an electric field of a microwave of 2.45 GHZ. A configuration of the electric field generation power source 106 also includes the microwave power source matching device 236. The microwave power source matching device 236 adjusts an impedance so as to prevent generation of a reflected wave in the waveguide 105.

The radio frequency power sources 232₁ to 232ₘ are disposed in a lower portion of the plasma processing apparatus 100. At least one radio frequency power source 232 is disposed in the plasma processing apparatus 100, and is electrically connected to a bias application electrode inside the wafer placement electrode 120 or the electrode base material 108. A set of the radio frequency power sources 232₁ to 232ₘ can output radio frequency power of a plurality of frequencies, and can switch the power of the frequencies every predetermined period, or one thereof can output 0 and the other thereof can output a predetermined value.

For example, the plasma processing apparatus 100 may include one radio frequency power source 232 capable of outputting radio frequency power by switching between 400 MHz and 800 MHZ, and the plurality of radio frequency power sources 232₁ to 232ₘ capable of outputting radio frequency power between 400 MHz and 1.2 MHz, respectively, may be used and outputs from the radio frequency power sources may be switched at predetermined intervals and supplied to the wafer placement electrode 120. In FIG. 3, when creating a power source conversion table, all the radio frequency power sources used for processing of the semiconductor wafer 109 are connected in a beaded manner, and are communicably connected to the hub 220a and the hub 220b, or the master device 210.

The radio frequency power source matching devices 233₁ to 233ₘ are disposed in the upper portion of the plasma processing apparatus 100 corresponding to the number of radio frequency power sources 232₁ to 232ₘ. When the plasma processing apparatus 100 includes one radio frequency power source 232 capable of outputting radio frequency power by switching between 400 MHz and 800 MHZ, the radio frequency power source matching device 233 corresponding to the switching between 400 MHz and 800 MHz is provided. When the plurality of radio frequency power sources 232₁ to 232ₘ capable of outputting radio frequency power of 400 MHZ and 1.2 MHz, respectively, are used in the plasma processing apparatus 100, the radio frequency power source matching devices 233₁ to 233ₘ corresponding to the number of the plurality of radio frequency power sources 232₁ to 232ₘ, and the radio frequency mixer 234 are provided in the plasma processing apparatus 100. In this example, the radio frequency power sources 232₁ to 232ₘ and the radio frequency power source matching devices 233₁ to 233ₘ are disposed in a manner of being divided into different slave device groups 230b1 and 230b2. In the slave device groups 230b1 and 230b2, even when specifications of the plasma processing apparatus 100 are changed according to required processing, work on the components (for example, replacement, addition, and function adjustment and change of the radio frequency power source or the radio frequency power source matching device) can be performed in parallel.

The mass flow controllers 231₁ to 231ₙ disposed on a path including the piping to which the processing gas is supplied are disposed in the lower portion of the plasma processing apparatus 100, and are collectively disposed in at least one box such that the pipelines formed by the mass flow controllers 231₁ to 231ₙ extend in parallel. At least some of the mass flow controllers 231₁ to 231ₙ can be replaced, removed, or changed based on a change in gas conditions such as a type and composition of a gas to be used according to processing conditions of the semiconductor wafer 109.

As described above, the plurality of components are categorized as groups according to functions such as supply of radio frequency power for bias, matching of radio frequency power for bias, supply of power for plasma formation or a magnetic field, and adjustment of an amount of a gas supplied into the processing chamber 104. The plurality of slave device groups 230b1, 230b2, 230c, and 230a include components categorized by function.

Different from FIG. 2, FIG. 3 shows two hubs, the slave device group 230b1 is connected to the hub 220a, and the slave device group 230b1 and the slave device groups 230b2, 230c, and 230a are connected to the hub 220b. In the control unit 170 according to the embodiment, the number of hubs 220 is not limited to one as long as at least one hub 220 is directly connected to the master device 210. When a plurality of hubs are provided, the hubs are communicably connected to one another in a beaded manner. Also in FIG. 3, the hub 220a is directly connected to the master device 210, and the hub 220a and the hub 220b are communicably connected to each other.

### (Component Replacement Work)

An operation of the plasma processing apparatus 100 when performing the maintenance work on the radio frequency power source (RF power source) 232₂ provided in the slave device group 230b1 and the mass flow controller (MFC) 231₂ provided in the slave device group 230a, which are surrounded by one-dot chain lines in FIG. 3, will be described below.

FIG. 4 is a flowchart schematically showing a flow of maintenance work on the plurality of components in the control unit and the slave device groups shown in FIG. 3. FIG. 4 shows a work flow when performing the maintenance work on the radio frequency power source 232₂ and the mass flow controller 231₂ shown in FIG. 3 in parallel. RF replacement work 508 indicates work performed on the predetermined radio frequency power source 232₂ among the plurality of radio frequency power sources in the slave device group 230b1, and MFC replacement work 509 indicates work performed on the predetermined mass flow controller 231₂ among the plurality of mass flow controllers in the slave device group 230a. The maintenance work according to the embodiment is work for replacing each device with a new device of the same type.

The overall flow of the work is as follows. When the work is started, advance preparation 501 for performing the maintenance work on the radio frequency power source 232₂ and the mass flow controller 231₁ is performed. Next, on the radio frequency power source 232₂ and the mass flow controller 231₁, pre-replacement work 502a and 502b before replacement are performed respectively, and then replacement work 503a and 503b are performed respectively. Thereafter, post-replacement confirmation work 504a and 504b for confirming whether the replacement work 503a and 503b are normally performed are performed respectively on the radio frequency power source 232₂ and the mass flow controller 231₁. Thereafter, conversion table creation 505 is further performed on the radio frequency power source 232₂.

Next, a step of a trial operating mode 506 is performed, and a test operation of the plasma processing apparatus 100 including the radio frequency power source 232₂ and the mass flow controller 231₂ replaced with new devices is performed. Further, a step of discharge characteristic confirmation 507 is performed on the replaced radio frequency power source 232₂, and predetermined characteristics of plasma formed in the plasma processing apparatus 100 are detected using the replaced radio frequency power source 232b. Through these steps, it is confirmed whether a defect or a failure occurs in the replacement work and the subsequent work. When it is confirmed that no defect or failure occurs, the work ends.

In FIG. 4, in a step of the advance preparation 501, common work is performed on the plasma processing apparatus 100 by a radio frequency power source matching device 233₂ and the mass flow controller 231₂. Further, in the trial operating mode 506, the plasma processing apparatus 100 is operated in a state in which the radio frequency power source matching device 233₂ and the mass flow controller 231₂ are replaced. The RF replacement work 508 indicates the work performed on the radio frequency power source 232₂, and the MFC replacement work 509 indicates the work performed on the mass flow controller 231₂. In the embodiment, it will be described below that the RF replacement work 508 and the MFC replacement work 509 can be performed in parallel.

### (Flowchart of Replacement Work)

When the step of the advance preparation 501 is started, first, the operation of the plasma processing apparatus 100 is changed to an operation in a mode for maintenance and inspection work (maintenance mode) through the control unit 170 (master device 210). Specifically, the master device 210 transmits a command signal for setting the maintenance mode to the components. When a component for which the maintenance mode is not set in advance is provided, an operating state suitable for performing maintenance and inspection work is set for such a component. Next, a pipe to which the mass flow controllers 231₁ to 231ₙ in the integrated gas box 181 are connected communicates with an exhaust pipe for vacuum exhaust, a gas is supplied into the processing chamber 104 from each of the mass flow controllers 231₁ to 231ₙ, and the inside of the processing chamber 104 and the inside of a gas supply path including the mass flow controllers 231₁ to 231ₙ are exhausted. Thereafter, the valves are closed, and flow rates of the mass flow controllers 231₁ to 231ₙ are set to 0. The advance preparation 501 is a step common to the RF replacement work 508 and the MFC replacement work 509.

Although the pre-replacement work 502a and 502b are performed after the work of the advance preparation 501, the maintenance work such as opening the inside of the processing chamber 104 to the atmosphere and cleaning or replacing a member disposed inside the processing chamber 104 by opening to the atmosphere may be performed in parallel with the work after the pre-replacement work 502a and 502b shown in FIG. 4.

Next, the pre-replacement work 502a and 502b are performed. In the RF replacement work 508 on the radio frequency power source 232₂, power supply to the radio frequency power source 232₂ is stopped by operating a power supply interruption device such as a breaker as the pre-replacement work 502a. In the MFC replacement work 509 on the mass flow controller 231₂, whether a gas leakage occurs on the gas supply path is confirmed (check a leakage) by the master device 210 as the pre-replacement work 502b. When it is confirmed that a leakage occurs, a position where the leakage occurs is detected to prevent the leakage. Whether an abnormality occurs in the mass flow controller 231₂ to be replaced is confirmed. Even when the power supply to the radio frequency power source 232₂ is stopped, since the master device 210 has a hot-connect function, the master device 210 can perform work for designating the mass flow controller 231₂ and confirming whether an abnormality occurs.

Next, the replacement work 503a for replacing the radio frequency power source 232₂ and the replacement work 503b for replacing the mass flow controller 231₂ are started. In the replacement work 503a, first, it is confirmed that the power supply to the radio frequency power source 232₂ is stopped and a power source of the radio frequency power source 232₂ is turned off, and then all wiring and piping connected to the radio frequency power source 232₂ are removed and the radio frequency power source 232₂ is removed. A new radio frequency power source 232₂ is newly attached, the wiring and piping are attached in a reverse order, and the power source is turned on. Thereafter, the power supply to the radio frequency power source 232₂ is resumed.

In the replacement work 503b on the mass flow controller 231₂, first, wiring and piping for communication and power supply connected and attached to the mass flow controller 231₂ are removed. Next, screws and bolts fixing the mass flow controller 231₂ to a bracket in the integrated gas box 181 are loosened and removed, and the mass flow controller 231₂ is removed from the bracket. Thereafter, a new mass flow controller 231₂ is attached and fixed to the bracket, and the wiring and piping are attached.

During the replacement work, identification symbols of the devices such as serial numbers before and after replacement of the radio frequency power source 232₂ and the mass flow controller 231₂ are confirmed and recorded.

Next, the post-replacement confirmation work 504a on the radio frequency power source 232b and the post-replacement confirmation work 504b on the mass flow controller 231₂ are performed. In the post-replacement confirmation work 504a, for the radio frequency power source 232₂, the radio frequency power source 232₂ is brought into a state of being supplied with power by stopping the power supply interruption device such as the breaker, and it is confirmed whether a problem in other devices of the plasma processing apparatus 100 occurs. Further, the master device 210 confirms that an ID (identification signal or identification symbol) of the EtherCAT of the radio frequency power source 232₂ in the slave device group 230b1 is a predetermined value.

Although the component itself may be different after the replacement, the master device 210 uses a fixed address, and thus handles the component connected to the network at the same address. In other words, for example, when an ID of the radio frequency power source 232₂ before replacement is RF2, the master device 210 can recognize a new radio frequency power source after replacement work connected at a position of the radio frequency power source 232₂ in the slave device group 230b2 as the radio frequency power source having the ID of RF2. When an ID of the mass flow controller 231₂ before replacement is MFC2, the master device 210 can recognize a new mass flow controller after replacement work connected at a position of the mass flow controller 231₂ in the slave device group 230a as the mass flow controller 231₂ having the ID of MFC2.

In the embodiment, IDs are individually set for the plurality of component devices connected to the slave device groups 230b1, 230b2, 230c, and 230a, and values of data and signals indicating the IDs set for the component devices are stored or held in, for example, the data storage unit 219. Data and a command signal corresponding to each component generated by the packet generation unit 212 as described above are associated with a signal indicating an ID, and are identified as a signal addressed to the component itself where a packet reaches, and an operation of the component device is adjusted according to the signal. Thereafter, the power supply to the radio frequency power source 232₂ is temporarily stopped, and then the radio frequency power source 232₂ is connected to an electronic device such as a PC for setting and is separately supplied with power, and an initial value for an operation of the radio frequency power source 232₂ is set.

In the post-replacement confirmation work 504b on the mass flow controller 231₂, the master device 210 checks a leakage again on the replaced mass flow controller 231₂ using a predetermined gas, for example, He, and then sets a zero point of the mass flow controller 231₂. Next, on a display (not shown) connected to the control unit 170, a value obtained by monitoring an operation of the mass flow controller 231₂, which is returned from the target mass flow controller 231₂ to the master device 210, is confirmed, and in particular, a value of a flow rate is recorded.

Thereafter, supply of a gas to the mass flow controllers 231₁ to 231ₙ in the integrated gas box 181 is started, and data including values of flow rates transmitted from the mass flow controllers 231₁ to 231ₙ are displayed on the display, and a value of the replaced mass flow controller 231₂ is confirmed to detect whether an abnormality occurs.

Subsequently, a step of the conversion table creation 505 is performed on the radio frequency power source 232₂. In this step, for the replaced and attached new radio frequency power source 232₂, an output of the radio frequency power source 232₂ is adjusted by the master device 210 such that a difference between a set value of the output of the radio frequency power source 232₂ and an actual output value is within a predetermined allowable range.

First, in a state in which the power supply to the radio frequency power source 232₂ is temporarily stopped, a separate power meter is connected to the radio frequency power source 232₂, and input and output values of the power meter corresponding to reference outputs according to a plurality of operating modes including a high output state and a low output state of the radio frequency power source 232₂ are set. Thereafter, in a state in which power is supplied to the radio frequency power source 232₂ and an output value of the radio frequency power source 232₂ is set to be the same as an output value of the power meter, the output value of the radio frequency power source 232₂ included in an EtherCAT signal returned from the radio frequency power source 232₂ displayed on the display connected to the control unit 170 is confirmed. When a difference between a monitor value of the output displayed on the display and the output value displayed on the power meter is larger than a threshold, the output of the radio frequency power source 232b is adjusted to a value within the allowable range.

After the above adjustment ends, the power meter is removed in a state in which power supply from the radio frequency power source 232₂ is stopped.

Next, the plasma processing apparatus 100 is shifted to a trial operating mode (AUTO standby mode) by the master device 210. In this state, plasma is formed inside the vacuum container 101 under a predetermined processing condition and processing is performed, discharge characteristics such as plasma discharge and plasma density while the plasma is being formed are detected in the processing, and it is determined whether the discharge characteristics satisfy a determination reference for defining a predetermined allowable range. When it is determined that the condition is satisfied, the replacement work ends.

When the maintenance work is performed on the components belonging to the slave device groups 230b1, 230b2, 230c, and 230a in the steps shown in FIG. 4, the work on the radio frequency power sources 232₁ to 232ₘ and the mass flow controllers 231₁ to 231ₙ can be performed in parallel in a plurality of continuous steps from the pre-replacement work 502a and 502b including the advance preparation 501 to the post-replacement confirmation work 504a and 504b and the conversion table creation 505 for the radio frequency power source 232.

### (Configuration of Comparative Example)

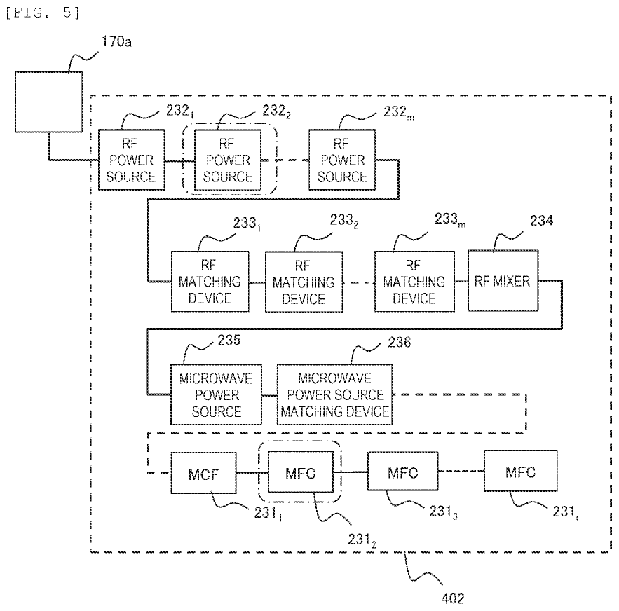

FIG. 5 is a block diagram schematically showing an example of a control unit and components connected thereto of a plasma processing apparatus as a comparative example with respect to FIG. 3. In FIG. 5, the radio frequency power sources 232₁ to 232ₘ are connected to a control unit 170a of the plasma processing apparatus in a beaded manner in this order. Further, on a downstream side of the radio frequency power source 232ₘ, the plurality of radio frequency power source matching devices 233₁ to 233ₘ respectively corresponding to the radio frequency power sources 232₁ to 232ₘ, and the radio frequency mixer 234 are connected in a beaded manner in this order.

Further, similarly, the microwave power source 235 for plasma formation of the plasma processing apparatus 100 and the microwave power source matching device 236, and the mass flow controller 231₁, the mass flow controller 231₂, and the mass flow controller 231₃ to the mass flow controller 231ₙ on a downstream side of the microwave power source 235 and the microwave power source device 236, are connected in a beaded manner. In this way, in the comparative example in FIG. 5, a plurality of components including the radio frequency power source 232₁ and 232₂ are connected in a beaded manner, and are communicably connected to one another and the control unit 170a, thereby forming one slave device group 402.

### (Replacement Work in Comparative Example)

In the comparative example, the radio frequency power sources 232₁ to 232ₘ, the radio frequency power source matching devices 233₁ to 233ₘ, the microwave power source 235, the microwave power source matching device 236, and the mass flow controllers 231₁ to 231ₙ are connected to one another as a slave device group in a beaded manner. Therefore, when replacing the radio frequency power source 232₂ and the mass flow controller 231₂, at least the steps of the pre-replacement work 502a and 502b cannot be performed in parallel, and one should be performed in order followed by the other.

For example, when performing the pre-replacement work 502a on the radio frequency power source 232₂ after the pre-replacement work 502b on the mass flow controller 231₂ is performed first, the replacement work 503b and the pre-replacement work 502a can be performed in parallel. However, thereafter, it is difficult to perform the steps of the replacement work 503a, the post-replacement confirmation work 504a, and the conversion table creation 505 on the radio frequency power source 232₂ in parallel with steps of work after the post-replacement confirmation work 504b on the mass flow controller 231₂. This is because the steps of the pre-replacement work 502a on the radio frequency power source 232₂ and the subsequent work up to the conversion table creation 505 include work performed by turning off power supply to the radio frequency power source 232₂. Therefore, the work using communication on the EtherCAT, such as confirming a value of data from the mass flow controller 231₂ after replacement of the mass flow controller 231₂ that is a component device connected on a downstream side of the radio frequency power source 232₂ belonging to a slave device group connected to the master device 210, cannot be performed unless power is supplied to the radio frequency power source 232₂.

In the comparative example, the same applies to a case where a series of radio frequency power sources including the radio frequency power source 232₂ is connected on a downstream side of the mass flow controller 231₂ with respect to the master device 210 in the slave device group 402. Even when the replacement work 503a and 503b are performed in parallel after one of the pre-replacement work 502a and 502b is performed in order followed by the other, it is difficult to perform the subsequent steps of the post-replacement confirmation work 504a and the conversion table creation 505 and step of the post-replacement confirmation work 504b in parallel as in the above case.

### (Operation and Effects)

In addition, in the embodiment, as described above, in the plurality of ports of the hub 220 connected to the master device 210 or the plurality of hubs 220a and 220b connected in a beaded manner, the plurality of slave device groups 230b1, 230b2, 230c, and 230a to which the plurality of component devices categorized as groups for functions belong are respectively provided for the radio frequency power sources 232₁ to 232ₘ, the radio frequency power source matching devices 233₁ to 233ₘ or the radio frequency mixer 234, the microwave power source 235 and the microwave power source matching device 236, and the mass flow controllers 231₁ to 231ₙ. Therefore, even when the maintenance work is performed on the component devices belonging to the plurality of slave device groups 230b1, 230b2, 230c, and 230a, the work can be performed in parallel, thereby shortening a work time, shortening a non-operation time of the plasma processing apparatus 100, and improving efficiency of the processing.

Even when the maintenance work is performed on any one of the component devices, since a component device connected on an upstream side of a slave device group to which the component device belongs with respect to the hub 220 can communicate with the master device 210 through the hub 220, the plasma processing apparatus 100 can operate using the component device on the upstream side. Accordingly, efficiency of the work performed on the plasma processing apparatus 100 can be improved.

### Embodiment 2

Embodiment 2 is different from Embodiment 1 in that a slave device group is further connected in a beaded manner to the slave device groups according to Embodiment 1. In the following description, components that are the same as or equivalent to those according to Embodiment 1 described above are denoted by the same reference numerals, and description thereof will be simplified or omitted.

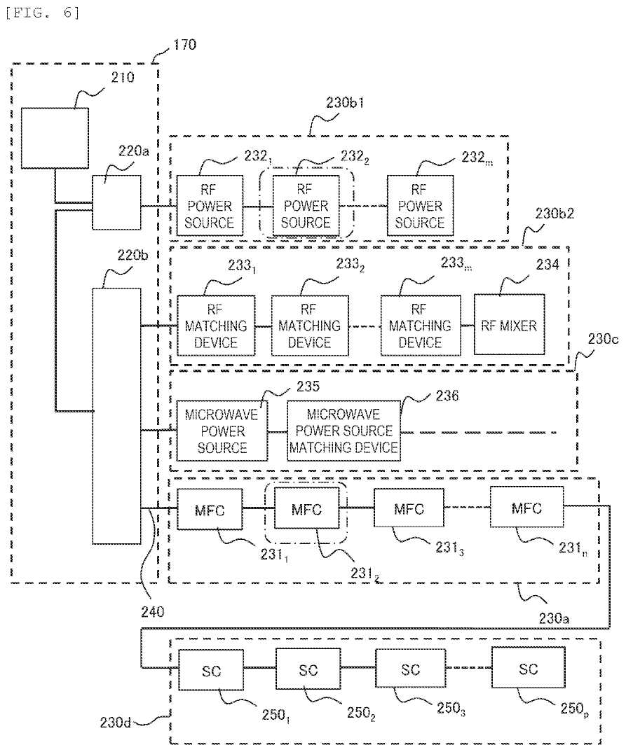

FIG. 6 is a block diagram schematically showing an example of the control unit 170 and slave device groups connected thereto of the plasma processing apparatus according to Embodiment 2. A slave device group 230d includes at least one component device among component devices excluding the component devices provided in the slave device groups 230b1, 230b2, 230c, and 230a from the plurality of components provided in the plasma processing apparatus 100.

The slave device group 230d includes a component 250₁, a component 250₂, a component 250₃, and up to a component 250ₚ (p is an integer of 1 or more). Here, the slave device group 230d and the slave device group 230a do not perform work on components (for example, replacement, addition, and function adjustment and change of a component) in parallel. The slave device group 230d is connected in a beaded manner to the slave device group 230a.

### Operation and Effects

In Embodiment 1, the slave device groups 230b1, 230b2, 230c, and 230a can perform work on components in parallel among the slave device groups. The hub 220 includes at least two ports, the slave device groups are respectively connected to the two ports, and the work on the components of the slave device groups can be performed in parallel.

In contrast, in Embodiment 2, the slave device group 230d is connected to the slave device group 230a in a beaded manner, and the slave device group 230d does not perform the work on the components in parallel with the slave device group 230a. By doing so, the slave device groups can be flexibly configured, and a degree of freedom in configuring a control network of the components provided in the plasma processing apparatus 100 can be improved. The number of ports of the hub 220 can be prevented from increasing, and measures for routing in wiring can be taken.

Although an example in which the slave device group 230d and the slave device group 230a are connected to one communication section of the hub 220 is shown, the present disclosure is not limited thereto. The slave device group 230d may not perform the work on the components in parallel with any one of the slave device groups 230b1, 230b2, and 230c. Although an example in which two slave device groups, namely the slave device group 230a and the slave device group 230d are connected in a beaded manner to one communication section of the hub 220b is shown, two or more slave device groups may be connected in a beaded manner.

Aspects that may be contents of the invention will be described below, but are not limited thereto.

### ASPECT 1

A manufacturing apparatus includes:
a plurality of component devices; and
a control unit configured to transmit data signals to the plurality of component devices, in which
the plurality of component devices are categorized as groups by a function, and have one or more groups including
   a first slave device group including at least one component device among the plurality of component devices, and
      a second slave device group including at least one component device among component devices excluding the component device provided in the first slave device group from the plurality of component devices, and
the control unit transmits the data signals to the first slave device group and the second slave device group.

### ASPECT 2

In the manufacturing apparatus according to Aspect 1,
the control unit includes
   a master device configured to generate the data signal, and
   a hub connected to the master device and including at least a first communication section and a second communication section,
the first slave device group is connected to the first communication section of the hub, and
the second slave device group is connected to the second communication section of the hub.

### ASPECT 3

In the manufacturing apparatus according to Aspect 1 or 2,
the control unit includes
   the master device configured to generate the data signal, and
   a master device side communication section configured to receive the data signal transmitted from the master device,
the first communication section receives the data signal from the master device side communication section and receives the data signal circuited in the first slave device group, and
the second communication section receives the data signal from the first communication section, receives the data signal circuited in the second slave device group, and transmits the data signal to the master device side communication section.

### ASPECT 4

In the manufacturing apparatus according to any one of Aspects 1 to 3,
the control unit, the first slave device group, and the second slave device group follow a communication method using EtherCAT.

### ASPECT 5

In the manufacturing apparatus according to any one of Aspects 1 to 4,
the first slave device group and the second slave device group include component devices categorized by a function, and
the first slave device group and the second slave device group perform work on the component devices in parallel.

### ASPECT 6

In the manufacturing apparatus according to any one of Aspects 1 to 5,
the plurality of component devices further include a third slave device group including at least one component device among component devices excluding the component device provided in the first slave device group and the component device provided in the second slave device group from the plurality of component devices,
the third slave device group and the first slave device group do not perform work on the component devices in parallel, and
the third slave device group is connected to the first slave device group in a beaded manner.

### ASPECT 7

In the manufacturing apparatus according to any one of Aspects 1 to 6,
the first slave device group includes a plurality of radio frequency power sources, and
the second slave device group includes a plurality of mass flow controllers.

### ASPECT 8

An operating method of the manufacturing apparatus according to any one of Aspects 1 to 7, in which
replacement work on a predetermined radio frequency power source among the plurality of radio frequency power sources in the first slave device group includes
   first pre-replacement work of stopping power supply to the predetermined radio frequency power source,
   first replacement work of replacing the predetermined radio frequency power source,
   first post-replacement confirmation work of supplying power to the replaced radio frequency power source, and
   a conversion table creation step of adjusting an output of the replaced radio frequency power source,
replacement work on a predetermined mass flow controller among the plurality of mass flow controllers in the second slave device group includes
   second pre-replacement work of checking a leakage,
   second replacement work of replacing the predetermined mass flow controller, and
   second post-replacement confirmation work of checking a leakage on the replaced mass flow controller, and
the replacement work on the predetermined radio frequency power source and the replacement work on the predetermined mass flow controller are capable of being performed in parallel.

### REFERENCE SIGNS LIST

100: plasma processing apparatus
101: vacuum container
102: shower plate
102a: gas introduction hole
103: dielectric window
104: processing chamber
105: waveguide
106: electric field generation power source
107: magnetic field generation coil
108: electrode base material
109: semiconductor wafer
110: vacuum exhaust port
111: conductor film
112: ground
113: susceptor ring
116: plasma
120: wafer placement electrode
120a: placement surface
120b: upper surface
124: radio frequency power source
125: radio frequency filter
126: DC power source
129: matching device
140: dielectric film
160: electric field and magnetic field formation unit
170, 170a: control unit
181: integrated gas box
185: vacuum pump
186: exhaust amount adjustment valve
210: master device
212: packet generation unit
213a to 213d: communication section (port)
214a to 214d: transmitter
215a to 215d: receiver
217: datagram generation unit
218: datagram analysis unit
219: data storage unit
220, 220a, 220b: hub
230a to 230d, 230b1, 230b2, 402: slave device group
231₁ to 231ₙ: mass flow controller (MFC)
232₁ to 232ₘ: radio frequency power source (RF power source)
233₁ to 233ₘ: radio frequency power source matching device (RF matching device)
234: radio frequency mixer (RF mixer)
235: microwave power source
236: microwave power source matching device
240: transmission path
250₁: to 250ₚ: component
1016: gas supply pipe
1017: opening and closing valve
1232: radio frequency power source

1. A manufacturing apparatus comprising:
a plurality of component devices; and
a control unit configured to transmit data signals to the plurality of component devices, wherein
the plurality of component devices are categorized as groups by a function, and have one or more groups including
a first slave device group including at least one component device among the plurality of component devices, and
a second slave device group including at least one component device among component devices excluding the component device provided in the first slave device group from the plurality of component devices, and
the control unit transmits the data signals to the first slave device group and the second slave device group.

2. The manufacturing apparatus according to claim 1, wherein
the control unit includes
a master device configured to generate the data signal, and
a hub connected to the master device and including at least a first communication section and a second communication section,
the first slave device group is connected to the first communication section of the hub, and
the second slave device group is connected to the second communication section of the hub.

3. The manufacturing apparatus according to claim 2, wherein
the control unit further includes
the master device configured to generate the data signal, and
a master device side communication section configured to receive the data signal transmitted from the master device,
the first communication section receives the data signal from the master device side communication section and receives the data signal circuited in the first slave device group, and
the second communication section receives the data signal from the first communication section, receives the data signal circuited in the second slave device group, and transmits the data signal to the master device side communication section.

4. The manufacturing apparatus according to claim 1, wherein
the control unit, the first slave device group, and the second slave device group follow a communication method using EtherCAT.

5. The manufacturing apparatus according to claim 1, wherein
the first slave device group and the second slave device group include component devices categorized by a function, and
the first slave device group and the second slave device group perform work on the component devices in parallel.

6. The manufacturing apparatus according to claim 1, wherein
the plurality of component devices further include a third slave device group including at least one component device among component devices excluding the component device provided in the first slave device group and the component device provided in the second slave device group from the plurality of component devices,
the third slave device group and the first slave device group do not perform work on the component devices in parallel, and
the third slave device group is connected to the first slave device group in a beaded manner.

7. The manufacturing apparatus according to claim 1, wherein
the first slave device group includes a plurality of radio frequency power sources, and
the second slave device group includes a plurality of mass flow controllers.

8. An operating method of the manufacturing apparatus according to claim 7, wherein
replacement work on a predetermined radio frequency power source among the plurality of radio frequency power sources in the first slave device group includes
first pre-replacement work of stopping power supply to the predetermined radio frequency power source,
first replacement work of replacing the predetermined radio frequency power source,
first post-replacement confirmation work of supplying power to the replaced radio frequency power source, and
a conversion table creation step of adjusting an output of the replaced radio frequency power source,
replacement work on a predetermined mass flow controller among the plurality of mass flow controllers in the second slave device group includes
second pre-replacement work of checking a leakage,
second replacement work of replacing the predetermined mass flow controller, and
second post-replacement confirmation work of checking a leakage on the replaced mass flow controller, and
the replacement work on the predetermined radio frequency power source and the replacement work on the predetermined mass flow controller are capable of being performed in parallel.
